(19) United States
(12) Patent Application Publication
(10) Pub. No.: US 2009/0140413 A1
(43) Pub. Date: Jun. 4, 2009

(54) SEMICONDUCTOR PACKAGE STRUCTURE, APPLICATIONS THEREOF AND MANUFACTURING METHOD OF THE SAME

(75) Inventors: Meng-Jen WANG, Ping Tung City (TW); Kuo-Pin Yang, Meinong Town (TW); Sheng-Yang Peng, Kaohsiung City (TW); Wei-Min Hsiao, Kaohsiung City (TW)

Correspondence Address: Muncy, Geissler, Olds & Lowe, PLLC, P.O. BOX 1364, FAIRFAX, VA, 22038-1364, US

(73) Assignee: ADVANCED SEMICONDUCTOR ENGINEERING INC.

(21) Appl. No.: 12/137,979

(22) Filed: Jun. 12, 2008

(30) Foreign Application Priority Data
Jun. 13, 2007 (TW) 96121418

(51) Int. Cl. H01L 23/48; H01L 21/60

(52) U.S. Cl. 257/698; 438/106; 257/E23.01; 257/E21.506; 257/416

(57) ABSTRACT

A semiconductor package structure and the applications thereof and the manufacturing method are disclosed. The semiconductor package structure includes a carrier, a semiconductor device, a first package body, a lid and a second package body. The semiconductor device is electrically connected to the carrier via a first conductive element. The first package body is molded on the carrier to surround the semiconductor device. The lid is disposed on top of the first package body and has at least one protrusion. The second package body is molded on the carrier to encapsulate the protrusion, whereby the protrusion is embedded within the second package body thereby locking the lid in place against the first package body.

### RELATED APPLICATIONS

This application claims priority to Taiwan Application Serial Number 96121418, filed Jun. 13, 2007, which is herein incorporated by reference.

### FIELD OF THE INVENTION

The present invention relates to a semiconductor package structure, the applications thereof and manufacturing method of the same, and more particularly relates to a semiconductor package structure including Micro-Electro-Mechanical Systems (MEMS).

### BACKGROUND OF THE INVENTION

Currently, small, thin and light cell phones are prevalent. Cell phone manufactures have been devoted to downsize cell phones to meet customer needs.

A microphone is a critical component in the cell phone and is therefore the first component to be affected when the cell phone is made smaller. Even now reducing the size of the microphone is a critical task for design engineers skilled in the art.

Most of conventional cell phones use electret condenser microphones (ECMs). Although ECMs have reached dimensions of 4 mm×1.5 mm without the acoustic boot, they are unlikely to shrink much further due to the bottleneck of the current technology on manufacturing ECMs. Therefore, ECMs are gradually substituted by micro-electro mechanical system (MEMS) microphones utilizing a miniaturized mechanism formed on a silicon substrate to achieve the same result as ECMs.

FIG. 1 illustrates a cross-section of a conventional semiconductor package structure 100 for a MEMS microphone 102. Traditionally, the MEMS microphone 102 is fixed on and electrically connected to a substrate 104 or a lead frame and surrounded by a package body 106 and a lid 108.

Typically, the MEMS microphones are packaged into an array of many individual units on a substrate to meet large-scale production requirements. During the manufacturing process, adhesive should be dispensed on top of the package body 106 of each unit, and a compression step is required to complete the bonding between the lid 108 and the package body 106, thereby complicating the process. In addition, the lid 108 is easily delaminated from the package body 106 due to poor bonding strength of the adhesive.

Therefore, it is desirable to provide a simplified process to manufacture an improved semiconductor package structure with a MEMS microphone.

### SUMMARY OF THE INVENTION

An aspect of the present invention is to provide a semiconductor package structure. The semiconductor package structure comprises a carrier, a semiconductor device, a first package body, a lid and a second package body. The semiconductor device that has an active surface and a rear surface is fixed on the carrier and electrically connected to the carrier via a first conductive element. The first package body is provided on the carrier and erected around the semiconductor device. The lid with at least one protrusion is disposed on top of the first package body. The second package body is provided on the carrier, wherein the protrusion portion of the lid is embedded in the second package body such that the lid is locked in place against the first package body.

Another aspect of the present invention is to provide a method to form semiconductor package structures. The method comprises steps as follows. Firstly, a plurality of first package bodies is formed on a carrier such that a plurality of process units in an array arrangement is defined on the carrier. A plurality of semiconductor devices are attached to the process units of the carrier, respectively. Subsequently, the semiconductor devices are electrically connected to the carrier. A lid is disposed on the first package bodies such that the lid is in contact with the first package bodies, wherein the lid has plurality of protrusions located outside the process units of the carrier. The protrusions of the lid are encapsulated against the carrier to form a second package body located outside the process units of the carrier. A singulation process is then conducted to obtain the semiconductor package structures.

A further aspect of the present invention is to provide another method of forming semiconductor package structures. The method comprises steps as follows. Firstly, a carrier including a plurality of process units identified in an array arrangement is provided. A plurality of semiconductor devices are attached to the process units of the carrier, respectively. The semiconductor devices are electrically connected to the process units of the carrier by a plurality of first conductive elements, respectively. A plurality of first package bodies are formed to encapsulate the semiconductor device against the carrier, wherein each of the first package bodies has a opening used to expose a portion of the carrier. A plurality of electronic elements are attached to the first package bodies, respectively. The electronic elements are electrically connected to the exposed portion of the carrier through the opening. A lid is disposed on the first package bodies such that the lid is in contact with the first package bodies, wherein the lid has a plurality of protrusions formed respectively corresponding to the process units of the carrier and located outside the first package bodies. A second package body is formed to encapsulate the protrusions of the lid against the carrier such that the lid is locked in place against the first package body. Finally, a singulation process is conducted to obtain the semiconductor package structures.

In the present invention, the lid is fixed on the first package body by conducting an encapsulating process thereby skipping the conventional adhesive-dispensing and compressing steps. Accordingly, the manufacturing process of the present invention is simplified. In addition, the prior-art problem of the lid's delamination from the package body can also be solved by the mechanical locking between the protrusion of the lid and the second package body

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawing, wherein:

FIG. 1 illustrates a cross-section of a conventional semiconductor package structure with a MEMS microphone.

FIG. 2A illustrates a cross-section of a semiconductor package structure with a MEMS microphone in accordance with one embodiment of the present invention.

FIG. 2B illustrates a cross-section of a semiconductor package structure with a MEMS microphone in accordance with another embodiment of the present invention.

FIG. 3A illustrates a block diagram of the manufacturing method for forming semiconductor package structures with MEMS microphones in accordance with one embodiment of the present invention.

FIGS. 3B-3F illustrate in cross-section major steps of fabrication of the semiconductor package structure shown in FIG. 2B.

FIG. 4 illustrates a cross-section of a semiconductor package structure with a MEMS microphone in accordance with another embodiment of the present invention.

FIG. 5A illustrates a block diagram of the manufacturing method for forming the semiconductor package structure with the MEMS microphone shown in FIG. 4.

FIGS. 5B-5G illustrate in cross-section major steps of fabrication of the semiconductor package structure shown in FIG. 4.

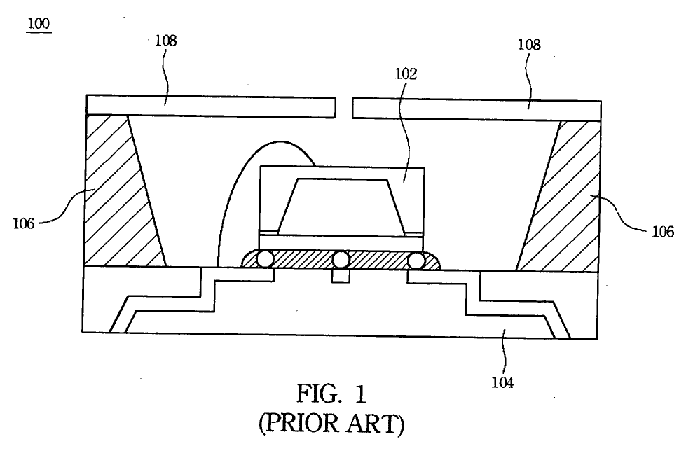

### DETAILED DESCRIPTION OF THE PREFERRED EMBODIMENT

The objectives of the present invention are to provide an improved method to form a semiconductor package structure with a MEMS microphone, wherein the semiconductor package structure have a lid more tightly fixed thereon in comparison with conventional package structures.

The foregoing aspects and many of the attendant advantages of this invention will become more readily appreciated as the same becomes better understood by reference to the following detailed description, when taken in conjunction with the accompanying drawings, wherein the preferred embodiment of the present invention described as follows is a semiconductor package structure with a MEMS microphone applied on a cell phone.

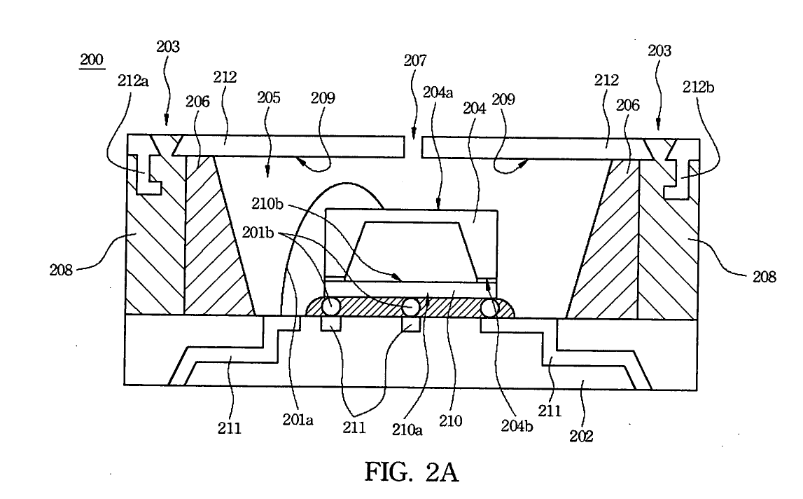

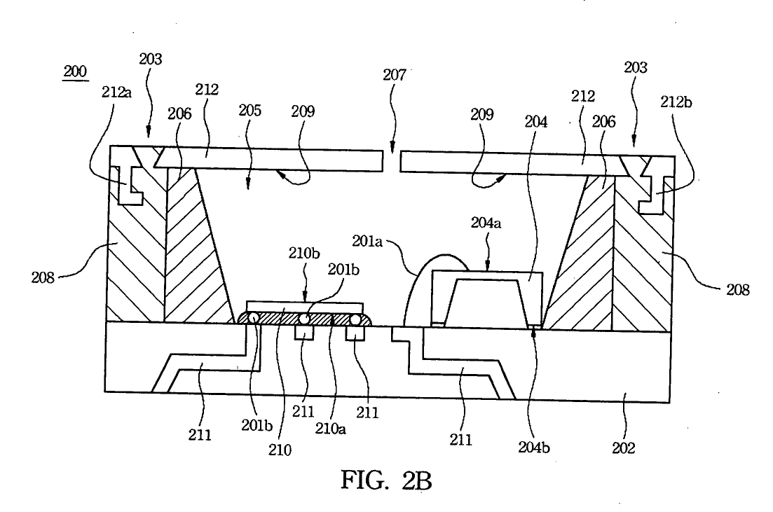

FIG. 2A illustrates a cross-section of a semiconductor package structure with a MEMS microphone in accordance with one embodiment of the present invention. FIG. 2B illustrates a cross-section of a semiconductor package structure with a MEMS microphone in accordance with another embodiment of the present invention. In these embodiments, the semiconductor package structure 200 comprises a carrier 202, an electronic element such as a MEMS microphone 204, a first package body 206, a lid 212 and a second package body 208.

The carrier 202 may be a wiring substrate or a lead frame. The MEMS microphone 204 is fixed on and electrically connected to the carrier 202. The MEMS microphone 204 is formed as a semiconductor chip with an active surface 204a and a rear surface 204b. The active surface 204a is electrically connected to the carrier 202 via either flip chip bumps or bonding wires. The signal generated by the MEMS microphone 204 can be transferred to an external system such as a cell phone (not shown) to conduct subsequence treatments via interconnects 211 formed in the carrier 202.

It is appreciated that the semiconductor package structure 200 may be further provided with another electronic element, which may be a semiconductor device or a passive component such as a resistor, a capacitor or an inductor. The arrangements of these electronic elements in the semiconductor package structure 200 may vary depending upon the requirement of different designs. For example, in the embodiment of FIG. 2A, a semiconductor device 210 with an active surface 210a is fixed on and electrically connected to the carrier 202 by a plurality of bumps 201b, and the rear surface 204b of the MEMS microphone 204 is fixed on the rear surface 210b of the semiconductor device 210. The active surface 204a of the MEMS microphone 204 is electrically connected to the carrier 202 via a bonding wire 201a. However, in another embodiment of FIG. 2B, the rear surface 204b of the MEMS microphone 204 is directly fixed on the carrier 202, and the active surface 204a of the MEMS microphone 204 is electrically connected to the carrier 202 via a bonding wire 201a.

The first package body 206 is formed on the carrier 202 and erected surround the MEMS microphone 204 and the semiconductor device 210.

The lid 212 is disposed on top of the first package body 206 and the total area of the lid 212 is greater than the area enclosed by the first package body 206. Thus, the lid 212, the first package body 206 and the carrier 202 together define a cavity 205 for receiving the MEMS microphone 204 and the semiconductor device 210 therein. In the present invention, the bottom surface 209 of the lid 212 in contact with the top surface of the package body 206 is provided with at least one protrusion, which is embodied as L-shaped protrusions 212a and 212b shown in FIGS. 2A and 2B, extending outside of the cavity 205.

Since the MEMS microphone 204 received in the cavity 205 should communicate with the external environment, the lid 212 has an aperture 207 to allow external acoustic energy to enter the MEMS microphone 204.

The second package body 208 is set on the carrier 202 to surround the package body 206 and to encapsulate the protrusions 212a and 212b, whereby the protrusions 212a and 212b are engaged within the second package body 208 thereby fixing the lid 212 to the package body 206. In addition, the lid 212 may further comprise at least one throughhole 203 to allow a portion of the second package body 208 to be formed within the throughhole 203 thereby enhancing the bonding between the lid 212 and the package body 208. Alternatively the at least one throughhole 203 can be substituted by at least one recess (not shown). In the present embodiment, the throughhole 203 extends from a first opening formed in the bottom surface 209 to a second opening formed in the top surface of the lid 212 wherein the first opening is smaller than the second opening thus giving the throughhole 203 a wedge-like shape thereby further enhancing the bonding between the lid 212 and the second package body 208.

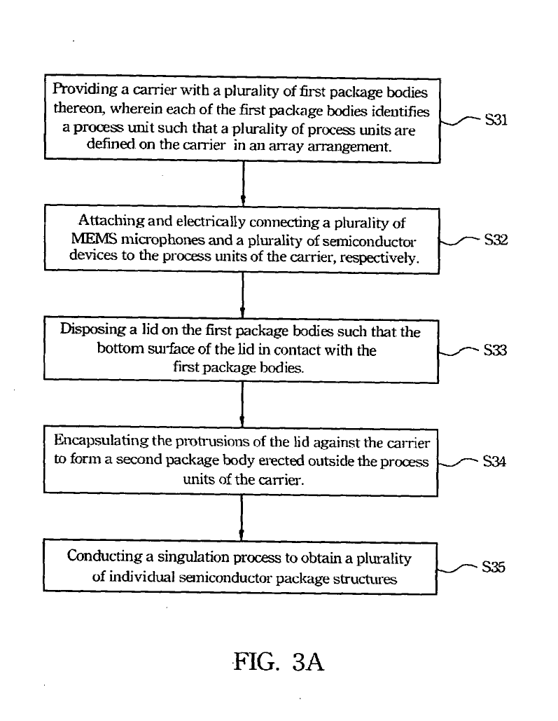

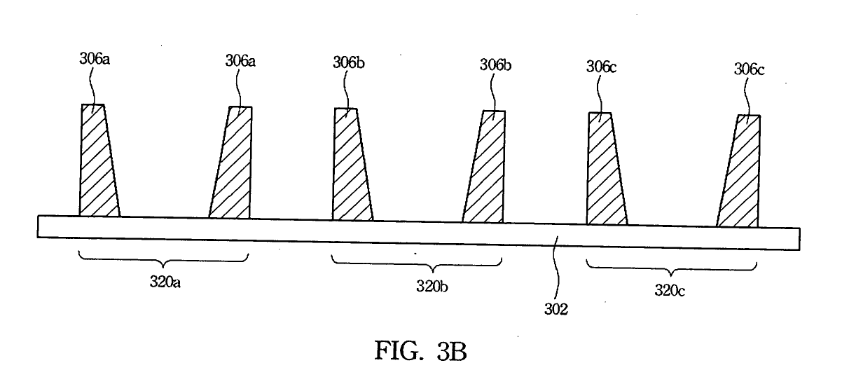

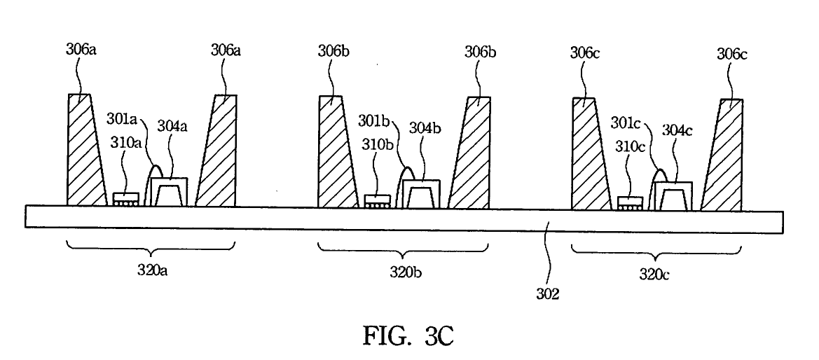

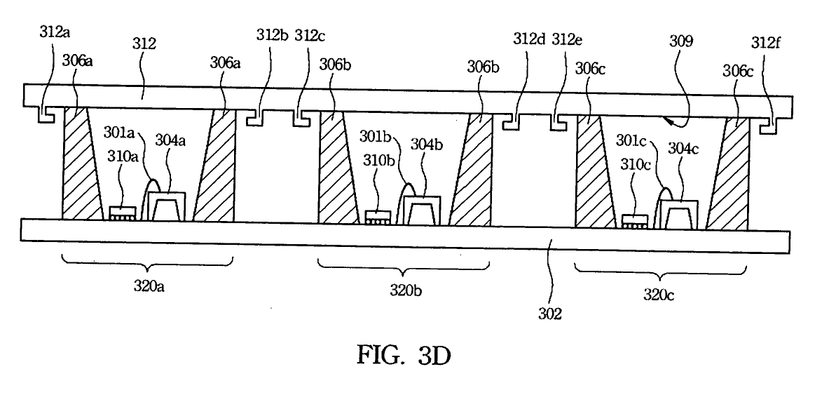

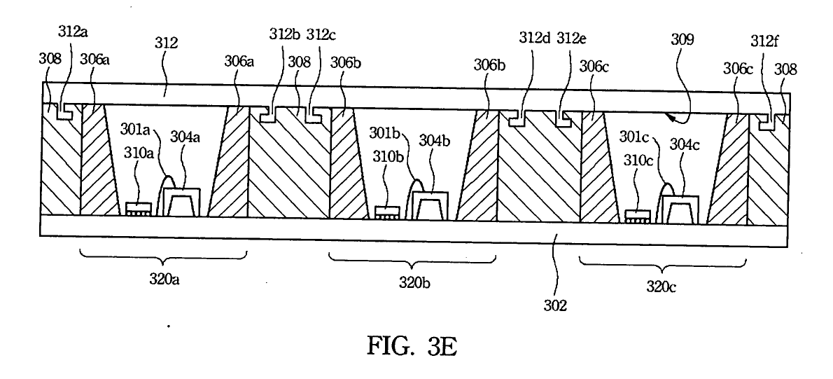

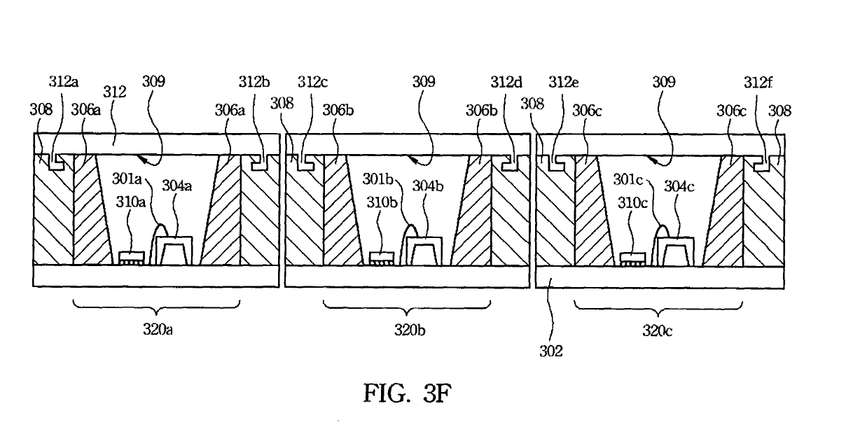

FIG. 3A illustrates a block diagram of the manufacturing method for forming the semiconductor package structure 200. The method can be embodied by the processing structures shown in FIGS. 3B-3F for forming the semiconductor package structure shown in FIG. 2B.

Referring to step S31 and FIG. 3B, a carrier 302 with a plurality of first package bodies 306a, 306b and 306c thereon are provided, wherein each of the first package bodies 306a, 306b and 306c identifies a process unit, such that a plurality of process units 320a, 320b or 320c are defined on the carrier 302 in an array arrangement. For example the area surrounded by the boundary of the package body 306a is defined as the process units 320a; the area surrounded by the boundary of the package body 306b is defined as the process units 320b; and the area surrounded by the boundary of the package body 306c is defined as the process units 320c.

Referring to step S32 and FIG. 3C, a plurality of MEMS microphones 304a, 304b and 304c and a plurality of semiconductor devices 310a, 310b and 310c are attached to and electrically connected to the process units 320a, 320b and 320c of the carrier 302, respectively. In the present invention, the MEMS microphones and the semiconductor devices may be electrically connected to the carrier 302 either via bonding wires or bumps.

Referring to step S33 and FIG. 3D, a lid 312 is disposed on the first package bodies 306a, 306b and 306c such that the bottom surface 309 of the lid 312 is in contact with the first package bodies 306a, 306b and 306c. The lid 312 has a plurality of protrusions 312a, 312b, 312c, 312d, 312e and 312f located outside the process units 320a, 320b and 320c of the carrier 302. In the present embodiment, each of these process units 320a, 320b and 320c is accompanied by two adjacent protrusions. For example, the protrusions 312a and 312b are formed adjacent to the process unit 320a; the protrusions 312c and 312d are formed adjacent to the process unit 320b; and the protrusions 312e and 312f are formed adjacent to the process unit 320c.

Referring to step S34 and FIG. 3E, the protrusions 312a, 312b, 312c, 312d, 312e and 312f of the lid 312 are then encapsulated against the carrier 302 to form a second package body 308 erected outside the process units 320a, 320b and 320c of the carrier 302. In the present embodiment, this encapsulating step may be accomplished by a molding process After the molding step is completed, the protrusion portions 312a, 312b, 312c, 312d, 312e and 312f of the lid 312 are embedded in the second package body 308 such that the lid 312 is locked in place against the first package bodies 306a, 306b and 306c.

Subsequently, a singulation process is conducted to cut the process structure of FIG. 3E into individual semiconductor package structures 300a, 300b and 300c (referring to step S35 and FIG. 3F).

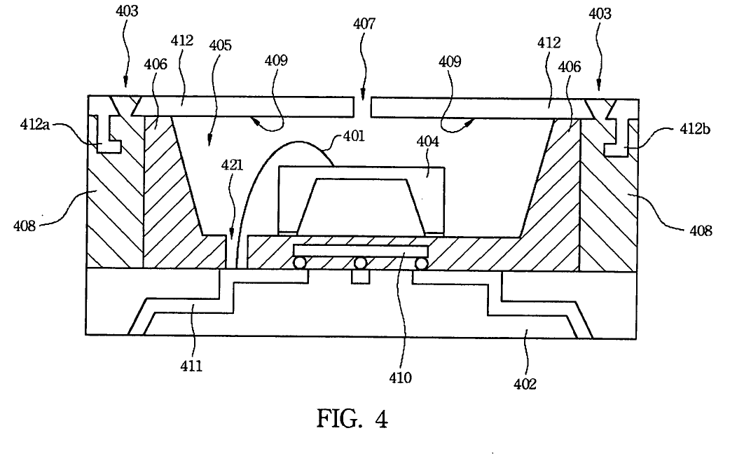

FIG. 4 illustrates a cross-section of a semiconductor package structure 400 with a MEMS microphone in accordance with another embodiment of the present invention. In the present embodiment, the semiconductor package structure 400 comprises a carrier 402, a MEMS microphone 404, a first package body 406, a lid 412 and a second package body 408.

The carrier 402 is a wiring substrate or a lead frame. A semiconductor device 410 is fixed on and electrically connected to the carrier 402. Alternatively, the semiconductor device 410 may be substituted by a passive component. In the present embodiment, the semiconductor device 410 is electrically connected to the carrier 402 via flip-chip bonding. Alternatively, the semiconductor device 410 may be electrically connected to the carrier 402 via wire bonding.

The first package body 406 with an opening 421 is formed on the semiconductor device 410 to encapsulate the semiconductor device 410 wherein a portion of the carrier 402 is exposed through the opening 421. The MEMS microphone 404 is fixed on the first package body 406 and electrically connected to the exposed portion of the carrier 402 by a bonding wire 401 passing through the opening 421.

The lid 412 is disposed on top of the first package body 406 and the total area of the lid 412 is greater than the area enclosed by the first package body 406. Thus, the lid 412, the first package body 406 and the carrier 402 together define a cavity 405 for receiving the MEMS microphone 404 therein. In this embodiment, the bottom surface 409 of the lid 412 in contact with the top surface of the first package body 406 is provided with at least one protrusion, which is embodied as L-shaped protrusions 412a and 412b, extending outside of the boundary of the first package body 406.

Since the MEMS microphone 404 enclosed in the cavity 405 should communicate with the external environment, the lid 412 has a aperture 407 to allow external acoustic energy to enter the MEMS microphone 404.

The second package body 408 is set on the carrier 402 to surround the first package body 406 and to encapsulate the protrusions 412a and 412b, whereby the protrusions 412a and 412b are engaged within the second package body 408 thereby fixing the lid 412 to the first package body 406. In addition, the lid 412 may further comprise at least one throughhole 403 to allow a portion of the second package body 408 to be formed within the throughhole 403 thereby enhancing the bonding between the lid 412 and the package body 408. Alternatively the at least one throughhole 403 can be substituted by at least one recess (not shown). In the present embodiment, the throughhole 403 extends from a first opening formed in the bottom surface 409 to a second opening formed in the top surface of the lid 412 wherein the first opening is smaller than the second opening thus giving the throughhole 403 a wedge-like shape thereby further locking the lid 412 onto the second package body 408.

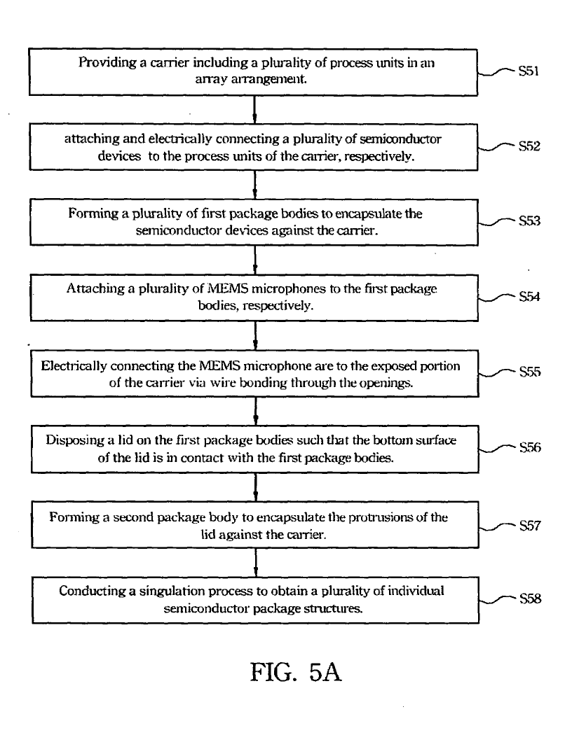

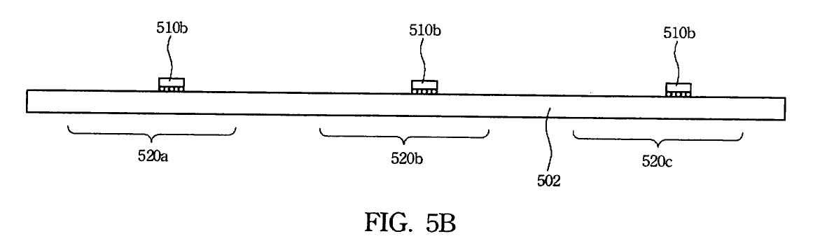

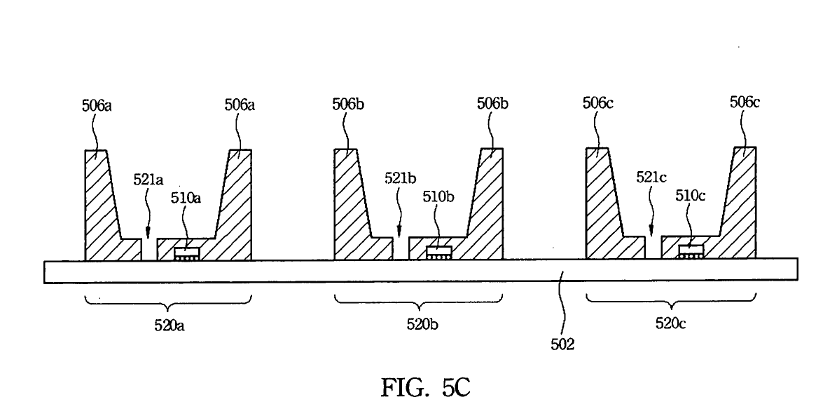

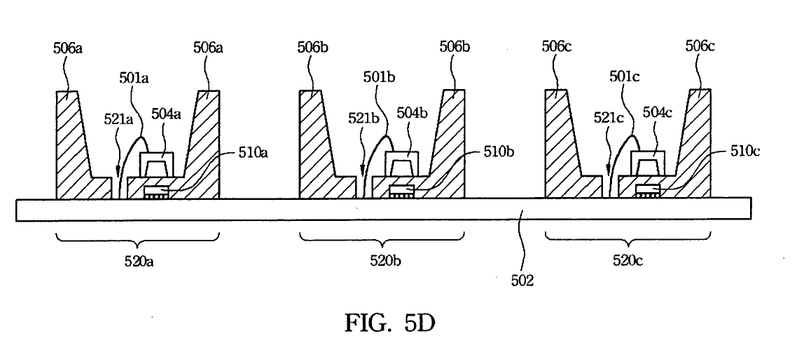

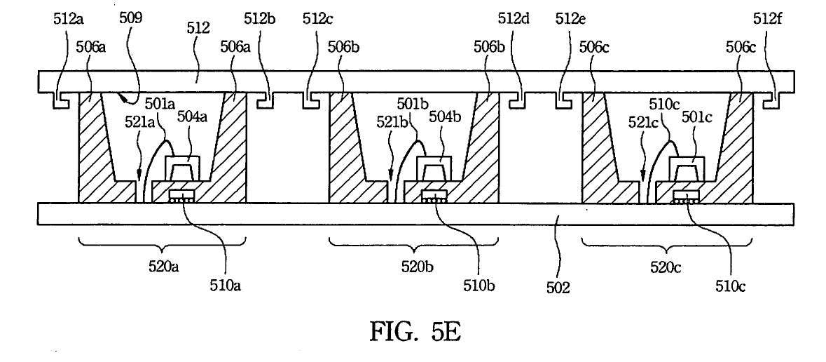

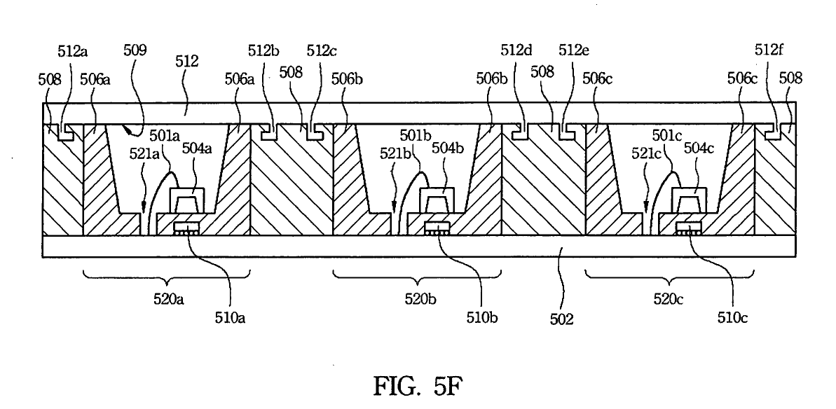

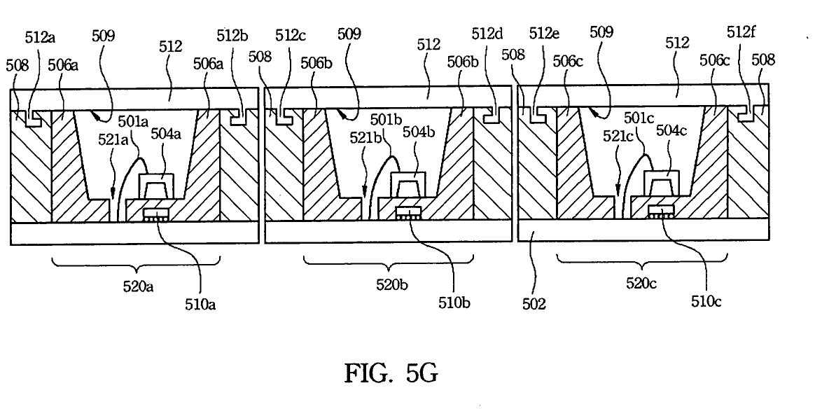

FIG. 5A illustrates a block diagram of the manufacturing method for forming the semiconductor package structure with the MEMS microphone shown in FIG. 4. FIGS. 5B-5G illustrate the processing structures for forming the semiconductor package structure shown in FIG. 4.

Referring to step S51 and FIG. 5B, a carrier 502 including a plurality of process units 502a, 502b and 502c in an array arrangement is provided.

Referring to step S52, a plurality of semiconductor devices 510b are attached and electrically connected to the process units 520a, 520b and 520c of the carrier 302, respectively. The semiconductor devices semiconductor device 510a, 510b and 510c may be electrically connected to the carrier 502 either via wire bonding or flip-chip bonding. In the present embodiment, the semiconductor devices 510a, 510b and 510c are electrically connected to the carrier 502 via flip-chip bonding.

Referring to step S53 and FIG. 5C, a plurality of first package bodies 506a, 506b and 506c are formed to encapsulate the semiconductor devices 510a, 510b and 510c against the carrier 502, wherein each of the first package bodies has at least one opening (e.g., 521a, 521b and 521c) used to expose a portion of the carrier 502. In the present embodiment, the first package bodies 506a, 506b and 506c are formed on the corresponding process unit 520a, 520b or 520c, respectively. For example, the first package body 506a is formed on the process unit 520a to encapsulate the semiconductor 510a; the first package body 506b is formed on the process unit 520b to encapsulate the semiconductor 510b; and the first package body 506c is formed on the process unit 520c to encapsulate the semiconductor 510c.

Referring to step S54 and FIG. 5D, a plurality of MEMS microphones 504a, 504b and 504c are attached to the first package bodies 506a, 506b and 506c, respectively. The MEMS microphone 504a, 504b and 504d are then electrically connected to the exposed portion of the carrier 502 via wire bonding through the openings 521a, 521b and 521c. (referring to step S55).

Referring to step S56 and FIG. 5E, a lid 512 is disposed on the first package bodies 506a, 506b and 506c such that the bottom surface 409 of the lid is in contact with the first package bodies 506a, 506b and 506c. The lid 512 has a plurality of protrusions 512a, 512b, 512c, 512d, 512e and 512f respectively formed corresponding to the process units 520a, 520b and 520c of the carrier 502 and located outside the first package bodies 506a, 506b and 506c. In the present embodiment, each of these process units 520a, 520b and 520c is accompanied by two adjacent protrusions. For example, the protrusions 512a and 512b are formed adjacent to the process unit 520a; the protrusions 512c and 512d are formed adjacent to the process unit 520b; and the protrusions 512e and 512f are formed adjacent to the process unit 520c.

Referring to step S57 and FIG. 5F, a second package body 508 is formed to encapsulate the protrusions 512a, 512b, 512c, 512d, 512e and 512f of the lid 512 against the carrier 502. In the present embodiment, this encapsulating step may be accomplished by a molding process whereby the protrusion portions 512a, 512b, 512c, 512d, 512e and 512f of the lid 512 are embedded in the second package body 508 such that the lid 512 is locked in place against the first package bodies 506a, 506b and 506c.

Subsequently, a singulation process is then conducted to cut the process structure of FIG. 5F into individual semiconductor package structures 500a, 500b and 500c (referring to step S58 and FIG. 5G).

In accordance with the embodiments of the present invention, the present invention is characterized by using a first package body to support a lid with at least one protrusion extending outside the first package body and forming a second package body to encapsulate the at least one protrusion of the lid thereby locking the lid in place against the first package body.

Hence, in the present invention, the lid is fixed on the first package body by conducting an encapsulating process thereby skipping the conventional adhesive-dispensing and compressing steps. Accordingly, the manufacturing process of the present invention is simplified. In addition, the prior-art problem of the lid's delamination from the package body can also be solved by the mechanical locking between the protrusion of the lid and the second package body.

As is understood by a person skilled in the art, the foregoing preferred embodiments of the present invention are illustrative, rather than limiting, of the present invention and are intended to cover various modifications and similar arrangements included within the spirit and scope of the appended claims, the scope of which should be accorded the broadest interpretation so as to surround all such modifications and similar structures.

What is claimed is:

1. A semiconductor package structure comprising:
a carrier;
a semiconductor device with an active surface and a rear surface, wherein the semiconductor device is fixed to the carrier and electrically connected to the carrier via a first conductive element;
a first package body provided on the carrier and erected around the semiconductor device;
a lid disposed on top of the first package body, the lid having a protrusion portion; and
a second package body provided on the carrier,
wherein the protrusion portion of the lid is embedded in the second package body such that the lid is locked in place against the first package body.

2. The semiconductor package structure in accordance with claim 1, wherein the protrusion portion of the lid forms an L shape.

3. The semiconductor package structure in accordance with claim 1, wherein the protrusion portion of the lid is located outside the first package body and the first package body is surrounded by the second package body.

4. The semiconductor package structure in accordance with claim 1, wherein the lid further comprises at least one recess or throughhole, and a portion of the second package body is formed within the at least one recess or through hole.

5. The semiconductor package structure in accordance with claim 1, wherein the first conductive element comprises a bump.

6. The semiconductor package structure in accordance with claim 5, further comprising:
an electronic element fixed on the rear surface of the semiconductor device; and
a second conductive element electrically connecting the electronic element and the carrier, wherein the first package body surrounds the electronic element and the semiconductor device.

7. The semiconductor package structure in accordance with claim 6, wherein the electronic element is a micro-electro mechanical system (MEMS) device.

8. The semiconductor package structure in accordance with claim 1, wherein the first conductive element comprises a bonding wire.

9. The semiconductor package structure in accordance with claim 1, wherein the first package body encapsulates the semiconductor device and has an opening to expose a portion of the carrier, and the semiconductor package structure further comprises:
an electronic element fixed on the first package body; and
a second conductive element electrically connecting the electronic element and the exposed portion of the carrier through the opening.

10. The semiconductor package structure in accordance with claim 9, wherein the second conductive element comprises a bonding wire.

11. The semiconductor package structure in accordance with claim 9, wherein the electronic element is a MEMS device.

12. The semiconductor package structure in accordance with claim 1, further comprising an electronic element set adjacent to the semiconductor device and electrically connected to the carrier.

13. The semiconductor package structure in accordance with claim 12, wherein the semiconductor device is a MEMS device, and the lid has an aperture formed therethrough.

14. The semiconductor package structure in accordance with claim 13, wherein the MEMS device is a MEMS microphone.

15. A method for forming a plurality of semiconductor package structures, the method comprising:
providing a carrier;
forming a plurality of first package bodies on the carrier such that a plurality of units in an array arrangement is defined on the carrier;
attaching a plurality of semiconductor devices to the units of the carrier, respectively;
electrically connecting the semiconductor devices to the carrier
disposing a lid on the first package bodies such that the lid is in contact with the first package bodies, wherein the lid has a plurality of protrusions located outside the units of the carrier;
encapsulating the protrusions of the lid against the carrier to form a second package body located outside the units of the carrier; and
conducting a singulation step to obtain the semiconductor package structures.

16. The method in accordance with claim 15, wherein the lid further comprises at least one recess or throughhole, and a portion of the second package body is formed within the at least one recess or throughhole of the lid during the step of forming the second package body.

17. The method in accordance with claim 15, further comprising:
attaching a plurality of electronic elements on the rear surfaces of the semiconductor devices, respectively; and
electrically connecting the electronic elements to the carrier, wherein the semiconductor devices are mounted on the carrier by flip-chip bonding.

18. The method in accordance with claim 15, further comprising:
attaching a plurality of electronic elements to the carrier at locations adjacent to the semiconductor devices, respectively; and
electrically connecting the electronic elements to the carrier.

19. A method for forming a plurality of semiconductor package structures, the method comprising:
providing a carrier including a plurality of units in an array arrangement;
attaching a plurality of semiconductor devices to the units of the carrier, respectively;
electrically connecting the semiconductor devices to the units of the carrier by a plurality of first conductive elements, respectively;
encapsulating the semiconductor devices against the carrier to form a plurality of first package bodies, respectively, wherein each of first package bodies has an opening to expose a portion of the carrier;
attaching a plurality of electronic elements to the first package bodies, respectively;
electrically connecting the electronic elements to the exposed portions of the carrier through the openings, respectively;
disposing a lid on the first package bodies such that the lid is in contact with the first package bodies wherein the lid has a plurality of protrusions formed respectively corresponding to the units of the carrier and located outside the first package bodies;
encapsulating the protrusions of the lid against the carrier to form a second package body; and
conducting a singulation step to obtain the semiconductor package structures.

20. The method in accordance with claim 19, wherein the lid further comprises at least one throughhole or one recess, and a portion of the second package body is formed within the at least one throughhole or one recess of the lid during the step of forming the second package body.
